(19) United States
(12) Patent Application Publication
(10) Pub. No.: US 2024/0047202 A1
(43) Pub. Date: Feb. 8, 2024

(54) TWO-DIMENSIONAL MATERIAL AND HETEROSTRUCTURES ON AN INTERMEDIATE POLYMER TRANSFER LAYER AND THEIR FABRICATION

(71) Applicant: DANMARKS TEKNISKE UNIVERSITET, Kongens Lyngby (DK)

(72) Inventors: Abhay Shivayogimath, Kongens Lyngby (DK); Peter Bøggild, Kongens Lyngby (DK); Timothy John Booth, Kongens Lyngby (DK)

(21) Appl. No.: 18/257,202

(22) PCT Filed: Dec. 14, 2021
(86) PCT No.: PCT/EP2021/085690

§ 371 Date: Jun. 13, 2023

(30) Foreign Application Priority Data
Dec. 14, 2020 (EP) 20213739.4

(51) Int. Cl. H01L 21/02; H01L 21/683

(52) U.S. Cl. CPC H01L 21/02527; H01L 21/0262; H01L 21/02002; H01L 21/02694; H01L 21/6835

(57) ABSTRACT

A method of manufacturing a water-soluble transfer stack comprising multilayer two-dimensional material includes: i. Providing a growth stack comprising a growth substrate and a two-dimensional material layer; ii. Applying an intercalating solution, to the growth stack; iii. Applying a transfer layer comprising a water-soluble polymer film, to the growth stack; iv. Delaminating the water-soluble polymer film together with the two-dimensional material layer, thereby obtaining a delaminated film, from the growth substrate; and v. Repeating steps i.-iv. a number of times, wherein the delaminated film is used as the transfer layer; thereby manufacturing a water-soluble transfer stack comprising multilayer two-dimensional material.

### CROSS-REFERENCE TO RELATED APPLICATIONS

This application is the U.S. National Stage of PCT/EP2021/085690 filed on Dec. 14, 2021, which claims priority to European Patent Application 20213739.4 filed on Dec. 14, 2020, the entire content of both are incorporated herein by reference in their entirety.

### FIELD OF THE INVENTION

The present disclosure relates to methods for manufacturing of water-soluble transfer layers comprising multiple layers of two-dimensional materials. In addition the present disclosure relates to water-soluble transfer layers, use of water-soluble transfer layers, and multilayer two-dimensional material.

### BACKGROUND OF THE INVENTION

Two-dimensional materials, such as graphene, are crystalline materials consisting of a single layer of atoms. These materials have proved to be highly useful in for example the fields of photovoltaics, semiconductors, electrodes and water purification.

Graphene is a crystalline allotrope of carbon in the form of a nearly transparent (to visible light) one atom thick sheet. Graphene is a very promising two-dimensional (2D) nano material that possesses extraordinary properties, including the highest known thermal and electrical conductivity and a strength that is hundreds of times higher than most steels by weight.

Typically, assembly of a product that uses graphene occurs remote from the production of the graphene layer, thereby the graphene is required to be transferred from the site of growth to the site of the target substrate. This is typically done by the application of a supporting poly methyl methacrylate (PMMA) film to the graphene followed by chemical etching of the metal substrate or by electrochemical delamination of graphene from the growth substrate.

Using this method, a layer of PMMA is spin-coated onto the graphene to act as a support. An etchant is then used to remove the metal catalyst, after which the PMMA/graphene stack may be transferred to the site of the target substrate. Solvents are then used to remove the PMMA, completing the graphene transfer.

However, transferring graphene using the PMMA method is not a simple procedure, and requires advanced knowledge including wet chemistry. A further issue is that it is costly as the catalyst accounts for a significant portion of the graphene production costs.

Other methods have been developed, such as electrochemical delamination, that allows for reuse of the catalyst. However, the throughput is significantly limited as the delamination rate must be kept low in order to prevent excessive bubbling that can damage the graphene film.

Another disadvantage with the transfer methods of the prior art is that they are not suitable for being used for transfer of multilayer graphene, or other two-dimensional material where control over the specific number of layers are required. Multilayer graphene has excellent characteristics, such as high electrical/thermal conductivities and current-carrying capacity, and is highly suited for a wide range of applications, including high performance transparent conductors, low-resistance wiring, and heat spreaders. Depending on the intended use of the multilayer graphene, i.e. the application, it requires a specific number of layers.

However, the production of single or multilayered graphene in a simple, efficient, cost-effective and scalable pathway is still a massive challenge in material science. Some initial efforts have been made for producing multilayer graphene by methods that build on aspects of production methods for single graphene layers. However, there is still no method that is capable of offering a scalable, non-hazardous and simple approach for the production of high-quality multilayer two-dimensional materials.

Consequently, there is a strong need for a simple and versatile method that allows for transfer or multilayer two-dimensional materials wherein the application of the transfer layer can be done without the use of specialized equipment or harsh chemicals, and that is highly suited for high-throughput processing.

### SUMMARY OF THE INVENTION

The present inventors have realized that water-soluble polymer films may advantageously be used for the sequential transfer of multilayer two-dimensional materials in a highly scalable way that allows for the reuse of the growth substrate, and which does not rely on the use of advanced equipment, highly trained personnel or hazardous chemicals. In fact, certain embodiments of the presently disclosed method rely on the use of water as an intercalating solution, for the decoupling of a two-dimensional layer from a growth substrate. This results in a method wherein the only solvent used is water.

The present disclosure therefore relates, in a first aspect, to a method of manufacturing a water-soluble transfer stack comprising multiple two-dimensional material layers, the method comprising:
Providing a growth stack comprising a growth substrate and a two-dimensional material layer;
Applying an intercalating solution, to the growth stack;
Applying a transfer layer comprising a water-soluble polymer film, to the growth stack;
Delaminating the water-soluble polymer film together with the two-dimensional material layer, thereby obtaining a delaminated film, from the growth substrate; and
Repeating steps i.-iv., a number of times, wherein for each repetition the most recently obtained delaminated film is used as the transfer layer;
thereby manufacturing a water-soluble transfer stack comprising multiple two-dimensional material layers.

The highly versatile method, based on the sequential transfer of the two-dimensional layers for the formation of the transfer stack, favorably allows for fabrication of transfer layers comprising any number of two-dimensional layers, and even transfer layers comprising different types of two-dimensional layers. The resulting transfer layer can readily be transported to an end-user for application onto a-product specific target substrate, negating the need for transporting the target substrate back and forth to the growth facilities. At the same time, the method allows for manufacturing of high-quality two-dimensional layers, with specific properties. For example for the fabrication of two-dimensional material layers with a significant roughness.

Roughened and wrinkled two-dimensional materials have shown to be highly useful in a wide range of applications, including electrodes, chemical detectors, mechanical sensors and controllable patterns, as further detailed in Chen, W. et al., (2018). Two-Dimensional Materials Wrinkling: Methods, Properties and Applications. Nanoscale Horizons.

In a preferred embodiment of the present disclosure, the method is configured such that at least part of the method is repeated. By repeating, at least one, part of the method further two-dimensional material layers may be added to the transfer stack. Wherein, in each repetition of said part of the method, a further two-dimensional material layer is added to the transfer stack. Thereby, by repeating the process a suitable number of times, a transfer stack having a desired number of two-dimensional material layers may be manufactured.

In addition to the fact that the method of manufacturing the transfer layer is simple to carry out, the end-product—the transfer layer itself—may also be applied to a target substrate with simple means. Additionally, neither the manufacturing of the transfer layer nor the application of the same to a target substrate, may require hazardous chemicals, highly trained personnel, or costly equipment.

The method is highly versatile, and may allow for the use of any conventional growth substrate. The growth substrate may even be provided as a metal foil, thereby allowing for increased throughput, for example by integrating the method in a roll-to-roll process. A significant advantage of the presently disclosed method, with respect to methods of prior art, is that it allows for reuse of the growth substrate. With the growth substrate accounting for a significant portion of the costs associated with the production of two-dimensional materials, a reusable growth substrate will lead to significantly lowered costs, and that the number of applications can be expanded.

In addition to the versatility in the choice of the two-dimensional material layer, the methods disclosed herein allows for manufacturing of water-soluble transfer layers comprising any number of two-dimensional material layers, such as at least two, more preferably at least 20. By repeating at least a part of the method, such as steps i.-iv., a suitable number of times, a water-soluble transfer stack comprising a corresponding number of two-dimensional material layers is produced.

It should be noted that the methods disclosed herein are not limited to specific materials of the two-dimensional material layers. Instead, the methods disclosed herein may be used for the formation of a water-soluble transfer stack comprising two-dimensional layers of different materials, thereby allowing for the fabrication of heterostructures in a process that is simple to carry out.

It is an object of the present disclosure to provide a method that at least in part is compatible with high throughput processing methods. For example, the method is compatible with roll-to-roll processing, for example by the use of a metal foil as the growth substrate, while application of the transfer layer to the growth stack may be done by the use of for example a hot roll laminator. The scalability of the process is an important aspect of the presently disclosed method.

In a preferred embodiment of the presently disclosed method, the application of the transfer layer to the growth stack is carried out in a single step, during application of heat and pressure, such as at least 140° C., and at least 2 bar. Such elevated temperatures and pressures negates the need for post-baking steps, acting to further simplify the method and increase the throughput.

In a further aspect, the present disclosure relates to a water-soluble transfer stack comprising multiple two-dimensional material layers. The water-soluble transfer stack is produced by a method comprising:
Providing a growth stack comprising a growth substrate and a two-dimensional material layer;
Applying an intercalating solution, to the growth stack;
Applying a transfer layer comprising a water-soluble polymer film, to the growth stack;
Delaminating the water-soluble polymer film together with the two-dimensional material layer, thereby obtaining a delaminated film, from the growth substrate; and
Repeating steps i.-iv., a number of times, wherein for each repetition the most recently obtained delaminated film is used as the transfer layer.

In a further aspect, the present disclosure relates to use of a water-soluble transfer stack for manufacturing multiple two-dimensional material layers on a target substrate, the use comprising
a. Obtaining a water-soluble transfer stack comprising multilayer two-dimensional material as disclosed elsewhere herein; and
b. Applying said water-soluble transfer stack to a target substrate; Thereby manufacturing multiple two-dimensional material layers on a target substrate.

In a further aspect, the present disclosure relates to multiple two-dimensional material layers. An object of the presently disclosed embodiment is to provide a multilayer two-dimensional material with a low degree of surface roughness, such as an average maximum height of roughness (Rz ISO) that is less than 50 nm. Preferably, the two-dimensional material has a surface area (footprint) of at least 1 cm².

### BRIEF DESCRIPTION OF DRAWINGS

FIG. 1 shows a schematic outline of a method of manufacturing a water-soluble transfer stack, according to a specific embodiment of the present disclosure;

FIG. 2 shows 4 samples of 3-layer graphene on water-soluble PVA foil, according to a specific embodiment of the present disclosure;

FIG. 3 shows multilayer graphene transferred onto different target substrates, according to a specific embodiment of the present disclosure;

FIG. 4 shows a photograph of daylight transmitted through a 3-layer graphene and optical transmittance of visible light through graphene of different layer numbers, according to a specific embodiment of the present disclosure;

FIG. 5 shows multilayer graphene on 90 nm SiO₂/Si substrates, according to a specific embodiment of the present disclosure;

FIG. 6 shows scanning electron microscopy (SEM) images of 3-layer graphene on a water-soluble PVA film, according to a specific embodiment of the present disclosure;

FIG. 7 shows atomic force microscopy (AFM) scans of 3 different samples of 3-layer graphene transferred to SiO₂/Si substrates, according to a specific embodiment of the present disclosure; and

FIG. 8 shows Raman point spectra taken for 3 different samples of 3-layer graphene transferred onto SiO₂/Si substrates, according to a specific embodiment of the present disclosure.

### DETAILED DESCRIPTION OF THE INVENTION

### Definitions

The term “two-dimensional material”, as used herein, refers to crystalline materials consisting of a single, or a few, layers of atoms. Typically, a material such as graphene is a single layer of atoms, while materials such as MXenes are a few atoms thick. This may also be referred to as single-layer materials. The joining of multiple, typically 2-100, two-dimensional material layers results in a stack comprising “multilayer two-dimensional materials”, also referred to herein as “multiple two-dimensional material layers”.

The term “growth substrate”, as used herein, refers to a substrate for the growth of a two-dimensional material. Typically the substrate is planar and provided in a material selected from a transition metal, such as copper, nickel or gold. The substrate is typically selected based on the lattice mismatch and interfacial strength between the substrate and the two-dimensional material.

The term “transfer stack” is used interchangeably herein with the term “transfer layer” and refers to a stack comprising a water-soluble polymer layer attached to at least one two-dimensional material layer. Upon repeating at least part of the method of the present disclosure, a two-dimensional material layer will be added to the transfer stack/transfer layer. The different layers of the transfer layer overlap at least partially, preferably said layers are of the same size and/or are aligned.

The term “intercalating solution”, as used herein, refers to the reversible inclusion or insertion of a molecule (or ion) into materials with layered structures. In a preferred embodiment of the present disclosure, water is used as an intercalating solution wherein water molecules are intercalated between a growth substrate and a two-dimensional material. Thereby, the intercalation solution is preferably configured such that it at least partly intercalates between the growth substrate and the two-dimensional material layer of the growth stack. The intercalation preferably leads to a decoupling such that the two-dimensional material layer may adhere stronger to a second layer, such as a transfer layer.

The term “water-soluble polymer film”, as used herein, refers to any film comprising polymers that is at least partially water soluble. A typical water-soluble polymer film is a film of poly(vinyl alcohol) (PVOH, PVA, or PVAI), with an idealized formula [CH₂CH(OH)]ₙ.

The term “vacuum”, as used herein, refers to a pressure well below atmospheric pressure (i.e. well below 1 atm). In particular vacuum refers to low, medium and/or high vacuum conditions (i.e. vacuum in the range 9.87×10⁻¹³ atm-3×10⁻² atm).

The term “vacuum deposition”, as used herein, refers to a family of processes used to deposit layers of material atom-by-atom or molecule-by-molecule on a solid surface, such as a growth substrate. These processes operate at pressures well below atmospheric pressure (i.e., vacuum). The deposited layers can range from a thickness of one atom up to millimeters, forming freestanding structures. Multiple layers of different materials can be used, for example to form optical coatings. The process can be qualified based on the vapor source; physical vapor deposition uses a liquid or solid source and chemical vapor deposition uses a chemical vapor.

In a first aspect, the present disclosure relates to a method of manufacturing a water-soluble transfer stack. The water-soluble transfer stack comprises at least two layers of one or more two-dimensional materials, i.e. said water-soluble transfer stack comprises multiple two-dimensional layers, wherein said layers are of the same and/or of different materials. A preferred embodiment of the present disclosure relates to a layer-by-layer formation of a transfer layer comprising multilayer two-dimensional material.

In an embodiment of the present disclosure, the repetition of at least a part of the method (step v) is carried out such that the method comprises:
Providing a growth stack comprising a growth substrate and a two-dimensional material layer;
Applying an intercalating solution, to the growth stack;
Applying a transfer layer comprising a water-soluble polymer film, to the growth stack;
Delaminating the water-soluble polymer film together with the two-dimensional material layer from the growth substrate, thereby obtaining a water-soluble transfer stack; and

Repeating the process with a further growth stack, by performing at least once:
a. Providing the further growth stack comprising a further two-dimensional material layer and the same or a further growth substrate;
b. Applying the intercalating solution to the further growth stack;
c. Applying the last obtained water-soluble transfer stack to the further growth stack;
d. Delaminating the water-soluble transfer stack together with the further growth stack from said same or further growth substrate, thereby obtaining a further water-soluble transfer stack (i.e. a water soluble transfer stack comprising a further two-dimensional material layer);
e. wherein, for each repetition, a further two-dimensional material layer is added to the water-soluble transfer stack, thereby manufacturing a water-soluble transfer stack comprising multiple two-dimensional material layers.

It is an object of the present disclosure to provide a water-soluble transfer stack that is easy to handle and to work with, e.g. to apply to a target substrate typically on a final product. Precise manufacturing of two-dimensional material, such as high quality graphene, is resource demanding and is an expensive process especially in order to obtain high throughput. Therefore, is a preference that the method is adapted such that the transfer stack is suitable to be manufactured at one location, typically the site of a two-dimensional material producer, and thereafter shipped to a second location, typically the site of the producer of an application-specific product, where the two-dimensional material is applied to a target substrate. Therefore, it is a strong preference that the transfer layer is easy to handle and to transport. In addition it may be a strong preference that the transfer layer is configured such that it is easy for a producer of an application-specific product to apply the two-dimensional material layers, of a transfer layer, to a target substrate of a product. The use of a water-soluble polymer film, for example a polyvinyl alcohol film, negates the need for otherwise harsh chemicals, allows for reusable growth substrates, while at the same time the process for applying said layers to the target substrate is simple to carry out.

In an embodiment of the present disclosure, the method involves the provision of a growth stack comprising a growth substrate and a two-dimensional material layer that has been grown on the growth substrate, for example by a vacuum deposition method such as chemical vapor deposition. A person skilled in the art however appreciates that there are other routes to formation of a two-dimensional layer that may be suitable for the provision of a two-dimensional layer in the presently disclosed method. The presently disclosed method is consequently not limited to any exemplary processes mentioned herein.

In an embodiment of the present disclosure, the intercalating solution and/or the conditions for application of the intercalating solution is configured such that at least part of the intercalating solution intercalates the growth stack, such as between the growth substrate and the two-dimensional material. Intercalation as used herein preferably refers to the reversible inclusion or insertion of a molecule (or ion) into materials with layered structures. The intercalating solution may thereby comprise parts, such as molecules, that intercalates between the growth substrate and the two-dimensional layer.

In a further embodiment of the present disclosure, the method comprises a step of applying a transfer layer comprising a water-soluble polymer film, to the growth stack. Said transfer layer may consequently consist of a single water-soluble polymer film layer. Typically the method is configured such that the method is, at least partly, repeated. The step of applying a transfer layer to the growth stack typically involves the use of a transfer layer that consists of a water-soluble polymer film for the first time said step is carried out. However, each time the step is repeated, the transfer layer will comprise an additional two-dimensional material layer. Thereby, the first time said step is repeated the transfer layer may consist of a water-soluble polymer film and a two-dimensional material layer. Each repetition of said step may involve the use of a transfer layer having n layers of a two-dimensional material layer, wherein n refers to the number of times the step is repeated.

In a further embodiment of the present disclosure, the method comprises a step of delaminating. Typically said step involves delamination of the water-soluble polymer film together with the two-dimensional material layer from the growth substrate, such that a delaminated film is obtained. The step of delamination preferably comprises delamination of the water-soluble polymer film together with each two-dimensional material layer. As it is a preference that a previous step involves the application of a transfer layer to a growth stack, the delamination typically involves the delamination of said transfer layer together with a two-dimensional layer of the growth stack, from the growth substrate. Typically the delamination step is configured such that the two-dimensional layer of the growth stack adheres stronger to the transfer layer, such as an exposed two-dimensional material layer of the transfer layer, than the growth substrate. In an embodiment of the present disclosure, delamination may consist or comprise mechanical delamination.

In a further embodiment of the present disclosure, at least parts of the method is repeated, preferably one or more steps comprising any of the following is repeated: providing a growth stack; applying an intercalating solution to a growth stack; applying a transfer layer to a growth stack; and/or delaminating a water-soluble polymer film together with a two-dimensional material layer from a growth substrate. In a preferred embodiment of the present disclosure all of the following is repeated: providing a growth stack; applying an intercalating solution to a growth stack; applying a transfer layer to a growth stack; and/or delaminating a water-soluble polymer film together with a two-dimensional material layer from a growth substrate.

In a further embodiment of the present disclosure method is arranged such that a water-soluble transfer stack comprising a multilayer two-dimensional material is produced, wherein the multilayer two-dimensional material may comprise any number of layers above one. As disclosed elsewhere herein, the two-dimensional material layers of said water-soluble transfer stack may comprise different materials, i.e. the two-dimensional material layers may comprise layers of different material. Thereby, the two-dimensional material layer may be a heterostructure.

Growth Stack

In a further embodiment of the present disclosure, the growth substrate comprises or consists of a metal substrate, for example a transition metal. In an embodiment of the present disclosure, the material of the growth substrate is any of iron, copper, nickel, gold, aluminum, silicon, gallium, tin or an oxide thereof, or an alloy thereof. In a further embodiment of the present disclosure, the growth substrate is provided as a metal foil. The use of metal foils may enable a higher throughput of the process, as it may enable roll-to-roll processing. Further, metal foils may be rolled up and occupy less space during an intercalation step.

In a further embodiment of the present disclosure, the step of providing the growth stack comprises growth of the two-dimensional material layer on the growth substrate, such as by chemical vapor deposition growth.

In a further embodiment of the present disclosure, the growth stack may comprise a growth substrate having multiple two-dimensional materials. For example, two-dimensional material layers may be grown on two opposite sides of a growth substrate, for example each side of a metal foil, thereby doubling the throughput. Therefore, in a further embodiment of the present disclosure, the step of providing the growth stack comprises growth of the two-dimensional material layer on two opposite sides of a growth substrate, such as by chemical vapor deposition growth.

In a further embodiment of the present disclosure, the method is configured such that upon repeating at least part of the method, such as for applying further two-dimensional layers to the growth stack, the growth substrate is reused a number of times for formation of further two-dimensional material layers. Unlike methods relying on the use of corrosive substances for release of a two-dimensional layer from a growth substrate, the presently disclosed method is preferably configured such that the growth substrate may be reused, thereby considerably decreasing the costs. The growth substrate may for example be reused for formation of further two-dimensional material layers of the same material. Thereby, a further growth substrate may be provided for each further material of the two-dimensional material layer.

In a further embodiment of the present disclosure, the material of the two-dimensional material layer is any of graphene, hexagonal boron nitride, and/or a transition metal dichalcogenides, such as molybdenum disulfide, hafnium disulfide, tungsten diselenide and/or MXene. The transfer stack may comprise a mixture of two-dimensional material layers of different materials. Thereby, in a further embodiment of the present disclosure, the water-soluble transfer stack comprises multiple two-dimensional material layers comprising layers of different two-dimensional materials.

The presently disclosed method enables manufacturing of a water-soluble transfer stack comprising large-area two-dimensional material layers. Therefore, in an embodiment of the presently disclosed invention, the two-dimensional material layers are each at least 1 cm², more preferably each at least each at least 10 cm², most preferably each at least 100 cm² (i.e. the surface area of one side of any one of the two-dimensional material layers).

Intercalation

In a further embodiment of the present disclosure, the intercalating solution comprises or consists of any of water, an alcohol solution (EtOH or IPA), a salt solution, such as sodium chloride, potassium chloride, such as 1M or less.

In a further embodiment of the present disclosure, the step of applying the intercalating solution is adapted such that the intercalating solution intercalates between the growth substrate and the two-dimensional material layer. For example, the process may take

place by intercalation of water in between the two-dimensional material layer and the growth substrate, after which the galvanic coupling between the more noble two-dimensional material layer (e.g. graphene film) and growth substrate (e.g. copper surface) leads to accelerated oxidation and corrosion of said surface and subsequent

decoupling of the two-dimensional material layer (e.g. graphene film) from the growth substrate (e.g. copper surface). A person skilled in the art knows that intercalation may be carried out by the use of different types of substances, and further, different methods for achieving intercalation, and ultimately decoupling of the layers. Intercalation may for example be achieved, alternatively or additionally to immersing in an intercalation solution, by electrochemical intercalation. However, in a preferred embodiment of the present disclosure, the intercalating solution comprises or consists of water. It is a strong preference that the method is configured such that it does not rely on any harsh chemicals. Thereby, the method may comprise intercalation in a step solely by application of water, and similarly, the transfer stack may be applied to a target substrate by dissolving the water-soluble by water.

In a further embodiment of the present disclosure, the intercalating solution is applied to the growth stack for less than 48 hours, preferably less than 24 hours, more preferably less than 12 hours, most preferably less than 8 hours. At the same time, the intercalating solution is applied to the growth stack for at least 30 minutes, more preferably at least 3 hours, most preferably at least 6 hours. In an embodiment of the present disclosure, the intercalating solution is applied to the growth stack for between 30 minutes and 12 hours, more preferably between 3 and 8 hours. In a further embodiment of the present disclosure, the intercalating solution is applied to the growth stack at a temperature of at least 20° C., more preferably at least 30° C., yet more preferably at least 45° C., even yet more preferably at least 60° C. An elevated temperature during the intercalation step may allow for a decreased length of said step, as the intercalation process may be accelerated.

Applying

It is a preference that the transfer layer is applied to the growth substrate following intercalation of the intercalation solution. Preferably the step of applying the transfer layer to the growth stack is configured such that the adhesion between the two-dimensional layer of the growth stack and the transfer layer, i.e. a water-soluble polymer film or an exposed two-dimensional material layer, is increased beyond the adhesion between the two-dimensional material layer of the growth stack and the growth substrate. In a preferred embodiment of the present disclosure, the step of applying the transfer layer to the growth stack comprises application of heat and/or pressure. The transfer layer, e.g. the water-soluble polymer film, may be applied by the use of a laminator. In a preferred embodiment of the present disclosure the transfer layer and the growth stack (preferably the intercalated growth stack) are laminated or hot-pressed at a temperature of 100° C.-180° C. and during application of a pressure between 2 bar and 5 bar. The step of applying the transfer layer to the growth stack, i.e. the lamination step, may be performed at ambient air pressure, however in a preferred embodiment of the present disclosure, the step of applying the transfer layer to the growth stack is performed in subatmospheric pressure, preferably low, medium, or high vacuum conditions.

In a preferred embodiment of the present disclosure, the temperature during the step of applying the transfer layer to the growth stack is at least 80° C., more preferably at least 100° C., yet more preferably at least 120° C., yet even more preferably at least 140° C., most preferably around 150° C., and/or preferably the temperature during the step of applying the transfer layer to the growth stack is applied for at least 1 s, more preferably at least 5 s, yet more preferably at least 10 s. In a preferred embodiment of the present disclosure, the temperature during the step of applying the transfer layer to the growth stack is at least 80° C., more preferably at least 100° C., yet more preferably at least 120° C., yet even more preferably at least 140° C., most preferably around 150° C., and/or preferably the temperature during the step of applying the transfer layer to the growth stack is applied for between 1 s and 20 s, more preferably between 2 s and 10 s, yet more preferably between 3 s and 7 s.

In a further embodiment of the present disclosure, the step of applying the transfer layer to the growth stack further comprises a post-baking step, performed at least at 80° C., more preferably at least at 100° C., yet more preferably at least at 120° C., most preferably at least at 140° C., such as for at least 30 s. The post-baking step may for example comprise application of heat by positioning the transfer layer and the growth stack on a hot plate. Typically, the post-baking step does not comprise application of pressure to the transfer layer and the growth stack. Specific embodiments of the present disclosure may not need a post-baking step, or may not even benefit from a post-baking step. For example, a higher temperature, such as at least 130° C., during the step of applying the transfer layer to the growth stack may negate the need for a post-baking step.

It should be noted that the transfer layer initially may consist of a water-soluble polymer film, such as before repeating at least part of the method. Following repetition of at least part of the method, the transfer layer typically comprises a water-soluble polymer film and at least one two-dimensional material layer. Therefore, in a further embodiment of the present disclosure, the application of heat and/or pressure comprises or consists of applying said heat and/or pressure to i. the water-soluble polymer film and the growth stack and/or ii. the delaminated film and a further growth stack.

In a further embodiment of the present disclosure, the transfer layer is applied to the growth stack by any of a roll laminator, such as a hot roll laminator, a roll-to-roll press, and/or a hot press. Preferably said roll laminator, hot roll laminator, roll-to-roll press, and/or hot press is configured to apply heat and/or pressure to the transfer layer and the growth stack such that their adhesion increases, preferably such that they adhere stronger than the adhesion between the growth substrate and the two-dimensional material layer of the growth stack.

Polymer Film

In a further embodiment of the present disclosure, the material of the water-soluble polymer film is polyvinyl alcohol. Polyvinyl alcohol or PVOH is a crystal clear, water soluble thermoplastic derived from polyvinyl acetate through partial or complete hydroxylation. PVOH is extremely hydrophilic which explains its good solubility in water and its high resistance to hydrocarbons, mineral oils, and many organic solvents such as ethers, esters, and ketones. Films made from polyvinyl alcohol have outstanding heat-sealing properties and exceptionally good adhesion to cellulose and other hydrophilic surfaces.

Preferably, the water-soluble polymer film is provided in a thickness that results in a degree of flexural rigidity sufficient for easy handling. For specific embodiments, said film is provided at the thickness that is sufficiently small for formation of a rolled-up transfer stack, for example wherein the method is implemented in a roll-to-roll processing. In a preferred embodiment of the present disclosure, the thickness of the water-soluble polymer film is between 100 nm and 100 μm.

Delaminating

In a further embodiment of the present disclosure, the step of delaminating comprises or consists of mechanically separating the water-soluble transfer layer and the two-dimensional layer of the growth stack from the growth substrate. Typically this leads to the formation of a transfer layer comprising an additional two-dimensional layer.

In a further embodiment of the present disclosure, the method is configured such that, for each time the steps are repeated, a further two-dimensional material layer is added to the water-soluble transfer stack. The further two-dimensional material layers may be of identical material and/or different materials.

In a further embodiment of the present disclosure, the method is repeated by applying a delaminated film, i.e. a stack comprising a water-soluble polymer film and at least one two-dimensional material layer, to a two-dimensional material layer, such as a two-dimensional material layer of a growth stack. Preferably the delaminated film is applied to a growth stack that has been subjected to an intercalating solution, preferably such that the intercalating solution at least partly has been intercalated between the two-dimensional layer of said growth stack and the growth substrate.

In a further embodiment of the present disclosure, the method is adapted to be performed in a roll-to-roll process.

In an embodiment of the present disclosure, the multilayer two-dimensional material has an electrical resistance of at most 10 kΩ/sq, preferably below 1 kΩ/sq. In a specific embodiment of the present disclosure, the water contact angle is between 30° and 90°. In a further embodiment of the present disclosure, the surface hardness is at most ˜10000 N/mm², as measured by nanoindentation technique.

A Water-Soluble Transfer Stack

In a further aspect, the present disclosure relates to a water-soluble transfer stack comprising multilayer two-dimensional material.

In an embodiment of the present disclosure, the water-soluble transfer stack has been manufactured according to a method of manufacturing a water-soluble transfer stack comprising multilayer two-dimensional material, as disclosed elsewhere herein.

In yet a further aspect, the present disclosure relates to a method for manufacturing a multilayer two-dimensional material on a target substrate, the method comprising:

Manufacturing a water-soluble transfer stack comprising multilayer two-dimensional material, comprising:
a. Providing a growth stack comprising a growth substrate and a two-dimensional material layer;
b. Applying an intercalating solution, to the growth stack;
c. Applying a transfer layer comprising a water-soluble polymer film, to the growth stack;
d. Delaminating the water-soluble polymer film together with the two-dimensional material layer, thereby obtaining a delaminated film, from the growth substrate; and
e. Repeating steps i.-iv. a number of times, wherein the delaminated film is used as the transfer layer; Applying said transfer stack to the target substrate.

In an embodiment of the present disclosure, the water-soluble transfer stack has been manufactured according to a method of manufacturing a water-soluble transfer stack comprising multilayer two-dimensional material, as disclosed elsewhere herein.

Use of a Water-Soluble Transfer Stack

In a further aspect, the present disclosure relates to use of a water-soluble transfer stack comprising multilayer two-dimensional material for manufacturing a multilayer two-dimensional material on a target substrate, the use comprising
a. Obtaining a water-soluble transfer stack, comprising:
   Providing a growth stack comprising a growth substrate and a two-dimensional material layer;
   Applying an intercalating solution, to the growth stack;
   Applying a transfer layer comprising a water-soluble polymer film, to the growth stack;
   Delaminating the water-soluble polymer film together with the two-dimensional material layer, thereby obtaining a delaminated film, from the growth substrate; and
   Repeating steps i.-iv. a number of times, wherein the delaminated film is used as the transfer layer;
a. Applying said water-soluble transfer stack to the target substrate;
b. Thereby manufacturing the multilayer two-dimensional material on the target substrate

In an embodiment of the present disclosure, the water-soluble transfer stack has been manufactured according to a method of manufacturing a water-soluble transfer stack comprising multilayer two-dimensional material, as disclosed elsewhere herein.

In an embodiment of the present disclosure, the multilayer two-dimensional material has a surface roughness (Ra) of less than 3 nm, preferably less than 2.5 nm, such as between 1 nm and 2.5 nm. In another embodiment of the present disclosure, the multilayer two-dimensional material has an average maximum height of roughness (R, ISO) of less than 50 nm, more preferably less than 30 nm, yet more preferably less than 15 nm. In a preferred embodiment, the multilayer two-dimensional material has three layers of one or more two-dimensional materials. In an embodiment of the present disclosure, the multilayer two-dimensional material is a heterostructure.

It is a preference that the transfer stack is applied to the target substrate prior to subjecting the transfer stack to water. In a preferred embodiment of the present disclosure, the step of applying the transfer stack to the target substrate comprises application of heat and/or pressure. The transfer stack may for example be applied by the use of a laminator. In a preferred embodiment of the present disclosure the transfer stack and the target substrate (preferably the intercalated target substrate) are laminated or hot-pressed at a temperature of between 100° C.-180° C. and/or during application of a pressure between 2 bar and 5 bar. The step of applying the transfer stack to the target substrate, i.e. the lamination step, may be performed at ambient air pressure, however in a preferred embodiment of the present disclosure, the step of applying the transfer stack to the target substrate is performed in subatmospheric pressure, preferably low, medium, or high vacuum conditions.

In a preferred embodiment of the present disclosure, the temperature during the step of applying the transfer stack to the target substrate is at least 80° C., more preferably at least 100° C., yet more preferably at least 120° C., yet even more preferably at least 140° C., most preferably around 150° C., such as for at least 3 s, more preferably at least 10 s.

In a further embodiment of the present disclosure, the step of applying the transfer stack to the target substrate further comprises a post-baking step, performed at least at 80° C., more preferably at least at 100° C., yet more preferably at least at 120° C., most preferably at least at 140° C., such as for at least 30 s. The post-baking step may for example comprise application of heat by positioning the transfer stack and the target substrate on a hot plate. Typically, the post-baking step does not comprise application of pressure to the transfer stack and the target substrate.

In a further embodiment of the present disclosure, the transfer stack is applied to the target substrate by any of a roll laminator, such as a hot roll laminator, a roll-to-roll press, and/or a hot press. Preferably said roll laminator, hot roll laminator, roll-to-roll press, and/or hot press is configured to apply heat and/or pressure to the transfer stack and the target substrate such that their adhesion increases, preferably such that they adhere stronger than the adhesion between the growth substrate and the two-dimensional material layer of the target substrate.

A Multilayer Two-Dimensional Material

In yet a further aspect, the present disclosure relates to a multilayer two-dimensional material. In an embodiment of the present disclosure, the multilayer two-dimensional material has a surface roughness (Ra) of less than 3 nm, preferably less than 2.5 nm, such as between 1 nm and 2.5 nm. In another embodiment of the present disclosure, the multilayer two-dimensional material has an average maximum height of roughness (R, ISO) of less than 50 nm, more preferably less than 30 nm, yet more preferably less than 15 nm. In a preferred embodiment, the multilayer two-dimensional material has three layers of one or more two-dimensional materials. In an embodiment of the present disclosure, the multilayer two-dimensional material is a heterostructure.

In an embodiment of the present disclosure, the material of the two-dimensional material layer is any of graphene, hexagonal boron nitride, and/or a transition metal dichalcogenides, such as molybdenum disulfide, hafnium disulfide and tungsten diselenide, or MXenes.

In an embodiment of the present disclosure, the two-dimensional material layer comprises multiple layers in different materials, for example selected from any of graphene, hexagonal boron nitride, and/or a transition metal dichalcogenides, such as molybdenum disulfide, hafnium disulfide and tungsten diselenide, or MXenes.

In an embodiment of the present disclosure, the surface area of each layer of the multilayer two-dimensional material is at least 1 cm².

In an embodiment of the present disclosure, the multilayer two-dimensional material is applied to a target substrate, such as SiO₂. The multilayer two-dimensional material may thereby cover a part of a target substrate.

In an embodiment of the present disclosure the 2D/G ratio is above 1. For example, the multilayer two-dimensional material may comprise three layers, such as three graphene layers, and have a 2D/G ratio above 1.

In an embodiment of the present disclosure, the multilayer two-dimensional material has an electrical resistance of at most 10 kΩ/sq, preferably below 1 kΩ/sq. In a specific embodiment of the present disclosure, the water contact angle is between 30° and 90°. In a further embodiment of the present disclosure, the surface hardness is at most ˜10000 N/mm², as measured by nanoindentation technique.

### DETAILED DESCRIPTION OF DRAWINGS

The invention will in the following be described in greater detail with reference to the accompanying drawings. The drawings are exemplary and are intended to illustrate some of the features of the presently disclosed methods of manufacturing a water-soluble transfer stack, water-soluble transfer stacks, multilayer two-dimensional materials, and use thereof, and are not to be construed as limiting to the presently disclosed invention.

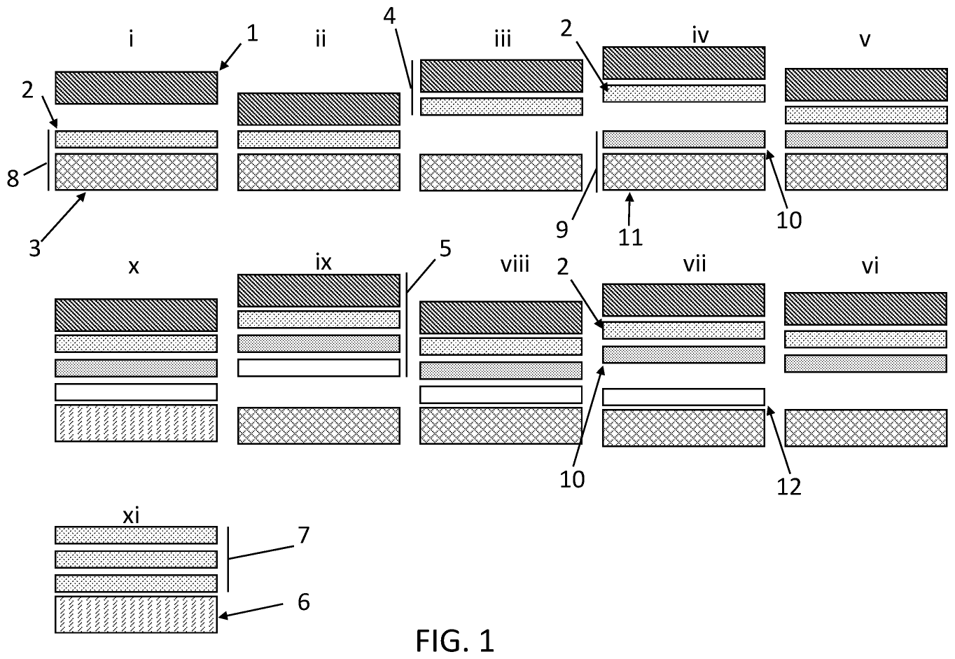

FIG. 1 shows a schematic outline of a method of manufacturing a water-soluble transfer stack comprising multilayer two-dimensional material, according to a specific embodiment of the present disclosure. (i-ii) A growth stack (8) is provided comprising a growth substrate (3) and a grown two-dimensional material layer (2). An intercalating solution, e.g. water, is applied to the growth stack (8) in order to facilitate decoupling of the two-dimensional material layer, for example by submerging the growth stack in the intercalating solution. A water-soluble polymer film (1) is thereafter brought into contact with the two-dimensional material layer (2) provided, e.g. grown, on the growth substrate (3). The resulting stack is laminated or hot-pressed at a temperature of between 100° C. and 180° C. and 2-5 bar pressure. Said pressure should be understood as the pressure mechanically applied to the objects, such as a mechanical laminating pressure. It should be noted that said pressure may be applied at various air pressures, for example vacuum pressure. In specific examples, said stack is also subjected to a post baking step. (iii) The polymer/graphene laminate (i.e. the water-soluble polymer film and the two-dimensional material layer(s)) is then mechanically delaminated from the growth substrate (3), forming a delaminated film (4).

(iv) The method is thereafter repeated a number of times, comprising providing a further growth stack (9) comprising a further two-dimensional material layer (10) and a further growth substrate (11), or the same growth substrate as previously if reused. The further two-dimensional layer may be identical or different (i.e. of a different material) from the two-dimensional layer of the delaminated film. The further growth stack (9) is subjected to the intercalating solution, typically by submerging the further growth stack in said solution. (v) Thereafter, the two-dimensional material layer (2) of the delaminated film (4) is brought into contact with the further two-dimensional layer (10) of the further growth stack (9), and the resulting stack is laminated or hot-pressed under the same conditions as in (i-ii). (vi) The polymer/graphene/graphene laminate is mechanically delaminated from the growth substrate producing a water-soluble transfer stack comprising two two-dimensional material layers.

The process may be repeated any number of times to produce transfer stacks comprising even more two-dimensional material layers, including two-dimensional material layers of different materials (for the formation of heterostructures. The repetition of the process is shown in steps vii-ix of FIG. 1 and comprises providing a further growth stacks, applying an intercalating solution to said further growth stack, and laminating or hot-pressing a two-dimensional layer of said water-soluble transfer stack comprising multiple (e.g. two) two-dimensional material layers to the further two-dimensional material of the further growth stack. The repetition is shown in vii-ix and comprises the provision of a further two-dimensional material layer (12), resulting in a water-soluble transfer stack (5) comprising three graphene layers on a water-soluble polymer (e.g. a PVA layer). While a method for manufacturing a water-soluble transfer stack comprising three layers of a two-dimensional material is shown, the steps can be repeated any number of times to manufacture n-layers of a two-dimensional material on a water-soluble polymer film. The transfer stack may for example comprise ten layers, twenty layers or even more two-dimensional layers, such as graphene and/or other two-dimensional material layers. In some examples, the transfer stack comprises a heterostructure comprising multiple layers of different two-dimensional materials.

The water-soluble transfer stack is preferably configured such that it can be easily transported to another site, typically wherein the multilayer two-dimensional material is applied to an application-specific target substrate. This is shown in x-xi, wherein the transfer stack is brought into contact with a target substrate (6) and hot-pressed or laminated. The water-soluble polymer film is subsequently dissolved in water (xi) leaving the multilayer two-dimensional material (7) on the target substrate (6).

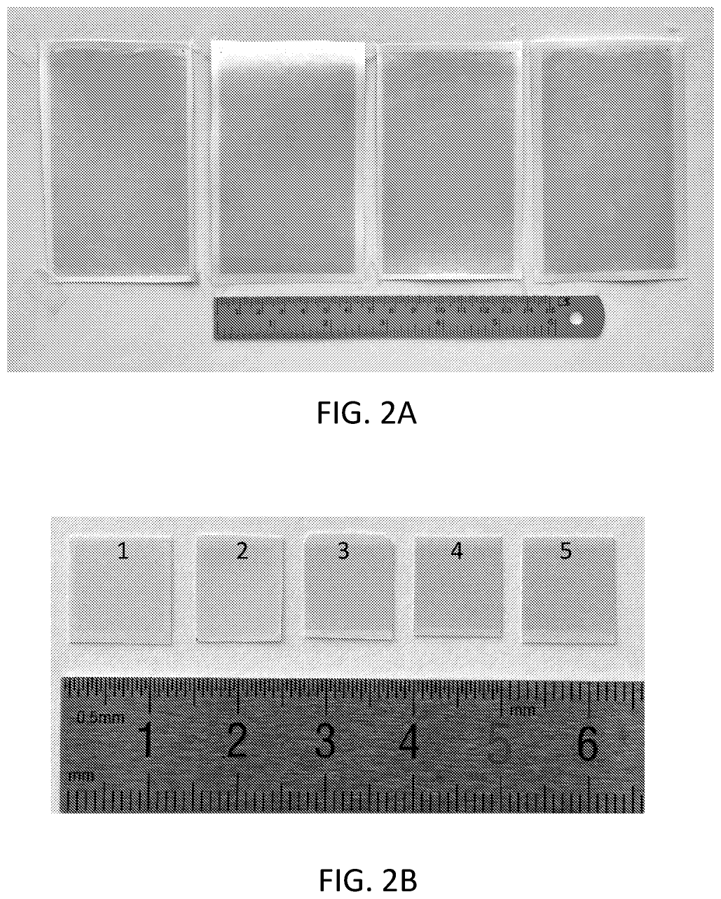

FIG. 2 shows (A) 4 samples of 3-layer graphene on water-soluble PVA foil with a white PET-based backing support, with a scale with centimeter dimensions included for reference, and (B) different number of graphene layers on PVA foil with backing support, with the number indicating the number of layers of graphene.

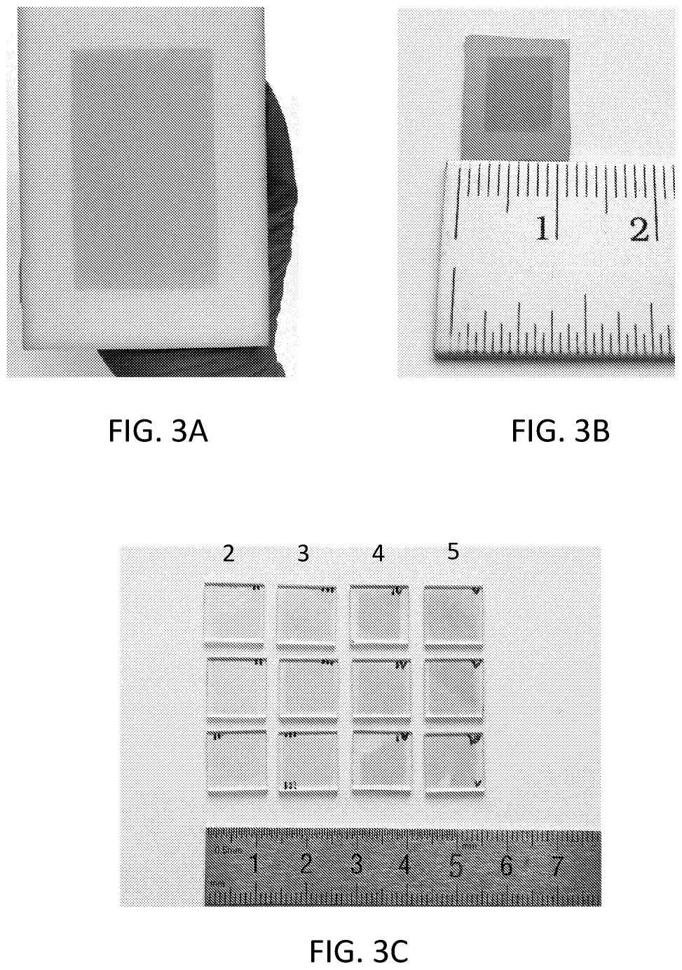

FIG. 3 shows multilayered graphene transferred onto different target substrates. (A) Three-layered graphene transferred to an acrylic substrate, (B) three-layered graphene transferred to a 90 nm thermally grown silicon oxide layer atop a silicon substrate (scale with centimeter dimension for reference), (C) graphene of different layer numbers on quartz target substrates. The number of layers for the samples of each column is provided in the figure.

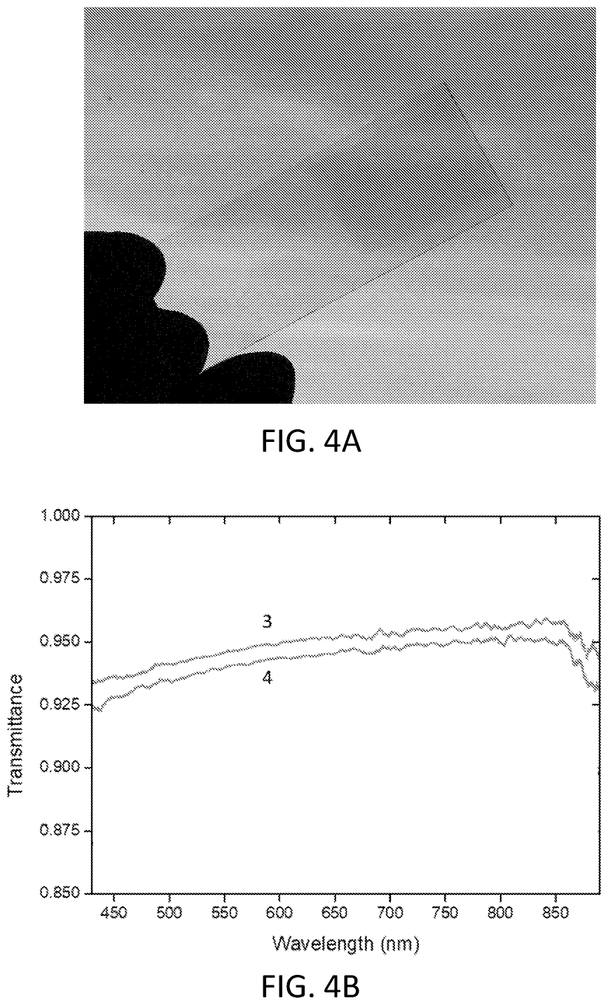

FIG. 4 depicts (A) a photograph of daylight transmitted through a 3-layer graphene transferred onto a glass target substrate, and (B) The optical transmittance of visible light through graphene of different layer numbers, as indicated in the plot.

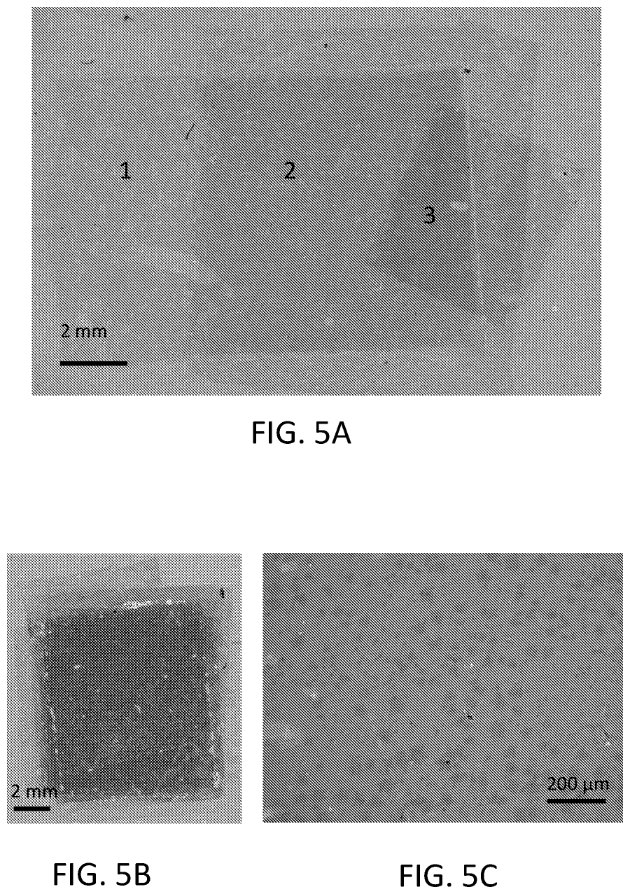

FIG. 5 shows multi-layered graphene on 90 nm SiO₂/Si substrates: (A) 3-layered graphene, with single layer, 2-layer, and 3-layer regions marked accordingly, (B) 15-layer graphene, (C) 3-layer graphene, where adlayers of graphene crystals can be seen, as well as holes in the top layers through which the 2nd and 1st layers can be seen.

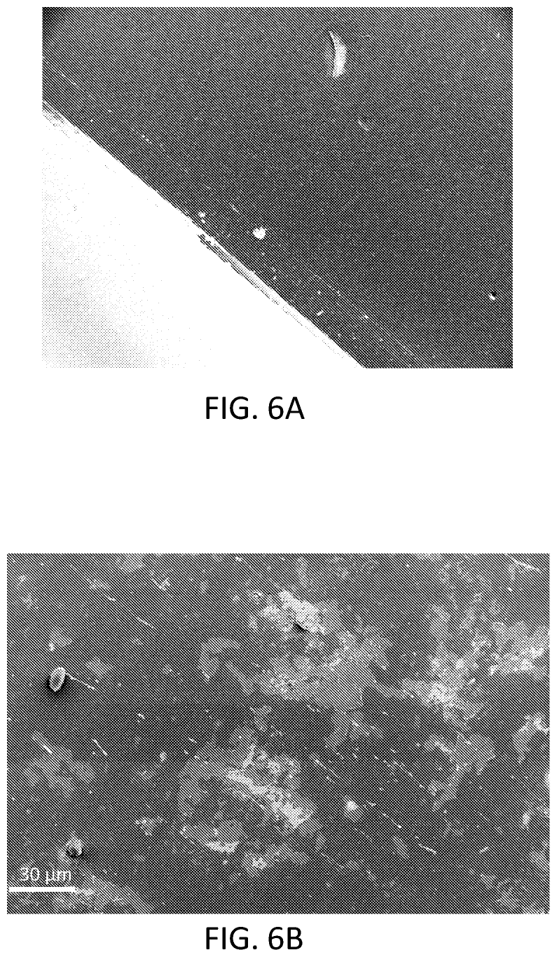

FIG. 6 shows scanning electron microscopy (SEM) images of 3-layer graphene on a water-soluble PVA film. SEM images were taken in a Zeiss Supra 40VP operated in (a) SE and (b) in-lens detection mode at 5 keV. In FIG. 6A, the white region in the lower left corner shows the bare PVA film, whereas the dark region shows the PVA film covered with 3-layer graphene. FIG. 6B shows a high magnification image of 3-layer graphene, with tears and holes in the topmost layer through which the second and first graphene layers can be seen.

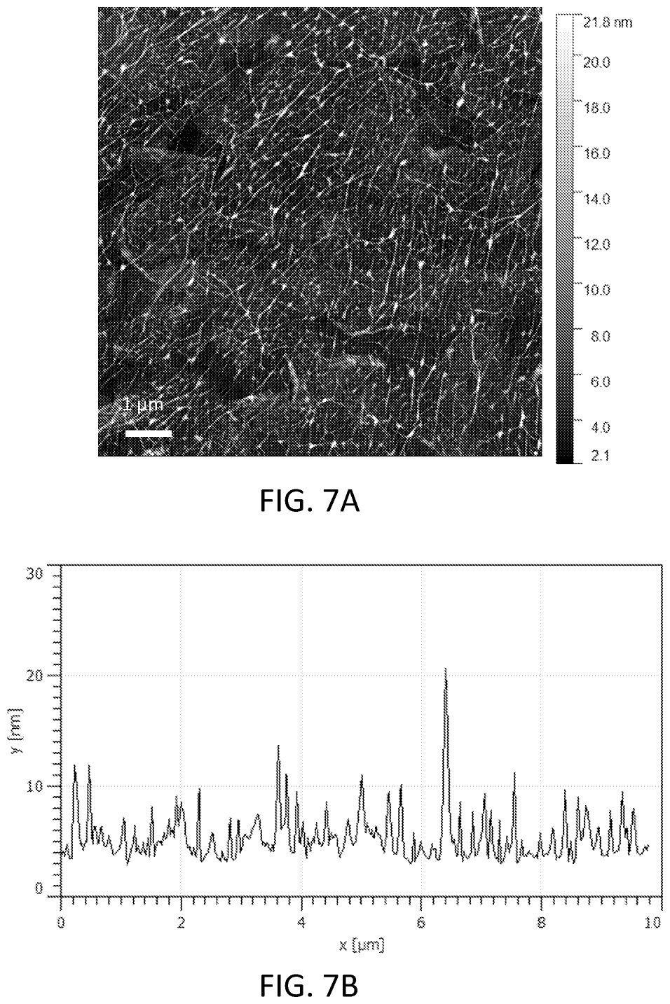

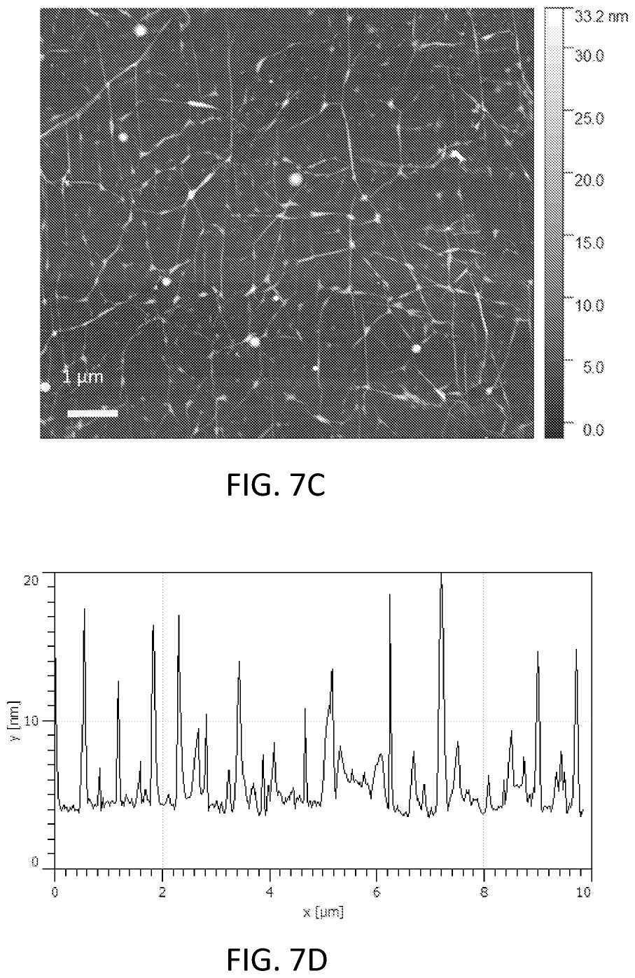

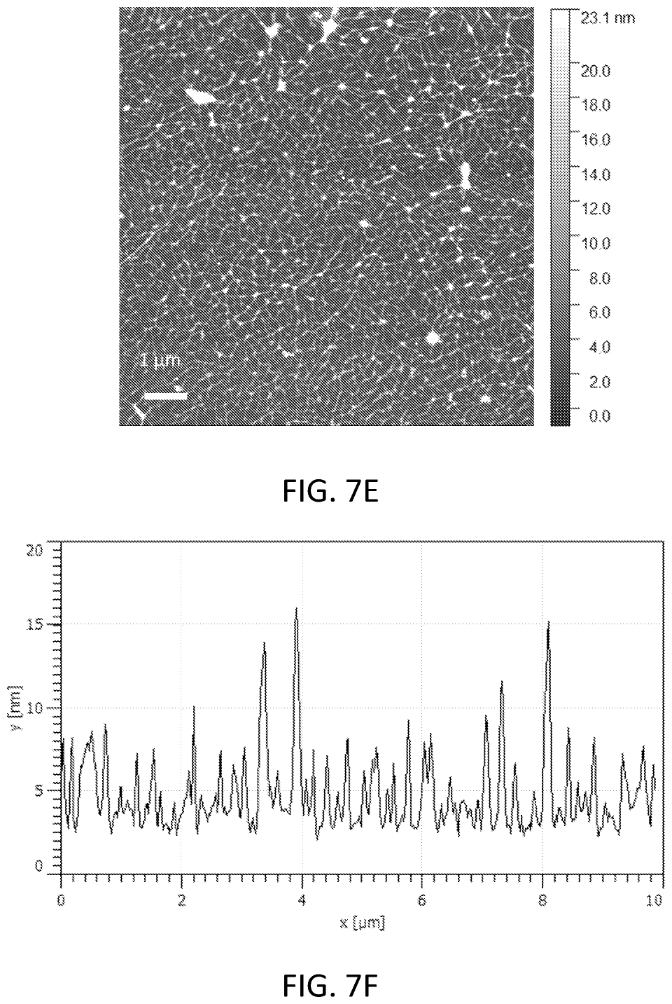

FIG. 7 shows atomic force microscopy (AFM) scans of 3 different samples of 3-layer graphene transferred to SiO₂/Si substrates, with their corresponding line scan profiles depicted below each respective scan. AFM was performed in a Bruker AFM Dimension Icon in tapping mode. The measurements results are summarized in table 1 below.

TABLE 1
AFM measurements

| | | Average maximum height |
|---|---|---|
| | Roughness (Ra) | of roughness (R_{z} ISO) |
| Sample 1 | 1.426 nm | 14.12 nm |
| Sample 2 | 2.383 nm | 15.75 nm |
| Sample 3 | 1.928 nm | 14.07 nm |
| Average | 1.912 | 14.65 nm |

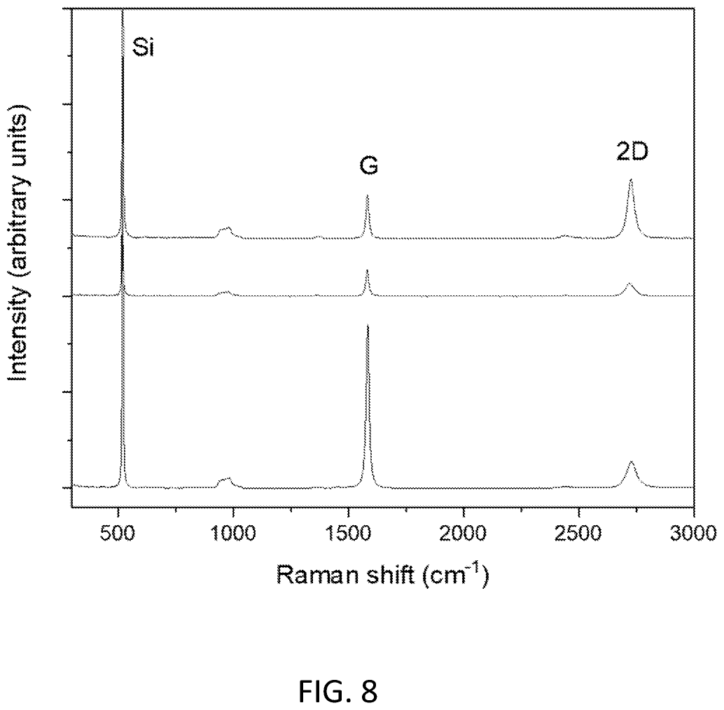

FIG. 8 shows Raman point spectra taken for 3 different samples of 3-layer graphene transferred onto SiO₂/Si substrates, where the 2D, G, and reference silicon peaks have been labelled. The G peak is typically significantly larger than the 2D peak, however in some samples and regions the 2D peak can be larger, displaying the degree of variation that can be seen in spectra from sample to sample, depending upon the stacking order of the graphene layers. The Raman peaks near 1000 cm⁻¹ are due to instrumental measurement artefacts and are to be ignored. Raman spectroscopy was performed in a Thermo Fisher DXR microscope equipped with a 455 nm laser, using an incident power of 5 mW and 10× objective, and 3 acquisitions with 10 s exposure time.

Further Details of the Present Disclosure
1. A method of manufacturing a water-soluble transfer stack comprising multilayer two-dimensional material, the method comprising:
   i. Providing a growth stack comprising a growth substrate and a two-dimensional material layer;
   ii. Applying an intercalating solution, to the growth stack;
   iii. Applying a transfer layer comprising a water-soluble polymer film, to the growth stack;
   iv. Delaminating the water-soluble polymer film together with the two-dimensional material layer, thereby obtaining a delaminated film, from the growth substrate; and
   v. Repeating steps i.-iv. a number of times, wherein the delaminated film is used as the transfer layer;
      thereby manufacturing a water-soluble transfer stack comprising multilayer two-dimensional material.
2. The method according to item 1, wherein the growth substrate comprises or consists of a metal substrate, such as a metal foil, such as comprising or consisting iron, copper, nickel, cobalt, gold, aluminum, silicon, gallium, tin or an oxide thereof.
3. The method according to any one of the preceding items, wherein the step of providing the growth stack comprises growth of the two-dimensional material layer on the growth substrate, such as by chemical vapor deposition growth.
4. The method according to any one of the preceding items, wherein, upon repeating said steps, the growth substrate is reused a number of times for formation of further two-dimensional material layers.
5. The method according to any one of the preceding items, wherein the material of any of the two-dimensional material layer is any of graphene, hexagonal boron nitride, and/or a transition metal dichalcogenides, such as molybdenum disulfide, hafnium disulfide, tungsten diselenide and/or MXenes.
6. The method according to any one of the preceding items, wherein the water-soluble transfer stack comprising multiple two-dimensional material layers comprises layers of different two-dimensional materials.
7. The method according to any one of the preceding items, wherein the surface area of each layer of the multilayer two-dimensional material is at least 1 cm².
8. The method according to any one of the preceding items, wherein the intercalating solution comprises or consists of any of water, an alcohol solution (EtOH or IPA), a salt solution, such as sodium chloride, potassium chloride, such as 1M or less.
9. The method according to any one of the preceding items, wherein the step of applying the intercalating solution is adapted such that the intercalating solution intercalates between the growth substrate and the two-dimensional material layer, such as by oxidizing the growth substrate.
10. The method according to any one of the preceding items, wherein the intercalating solution comprises or consists of water.
11. The method according to any one of the preceding items, wherein the intercalating solution is applied to the growth substrate for less than 48 hours, preferably less than 24 hours, more preferably less than 16 hours, yet more preferably less than 12 hours, even more preferably less than 8 hours, most preferably less than 4 hours.
12. The method according to any one of the preceding items, wherein the intercalating solution is applied to the growth substrate at a temperature of at least 40° C.
13. The method according to any one of the preceding items, wherein the step of applying the transfer layer to the growth stack comprises application of vacuum, such as low or medium vacuum.
14. The method according to any one of the preceding items, wherein the step of applying the transfer layer to the growth stack comprises application of heat and/or pressure.
15. The method according to item 14, wherein the application of heat and/or pressure comprises or consists of applying said heat and/or pressure to i. the water-soluble polymer film and the growth stack and/or ii. the delaminated film and a further growth stack.
16. The method according to any one of items 14-15, wherein the temperature, during application of the transfer layer to the growth stack, is at least 80° C., more preferably at least 100° C., yet more preferably at least 120° C. yet even more preferably at least 140 QC, most preferably around 150° C.
17. The method according to any one of items 14-16, wherein the step of applying the transfer layer to the growth stack comprises a post-baking step, performed at least at ° C., more preferably at least at 100° C., yet more preferably at least at 120° C., most preferably at least at 140° C., such as for at least 30 s.
18. The method according to any one of the preceding items, wherein the transfer layer is applied to the growth stack by any of a roll laminator, a hot roll laminator, a roll-to-roll press, and/or a hot press.
19. The method according to any one of the preceding items, wherein the material of the water-soluble polymer film is polyvinyl alcohol.
20. The method according to any one of the preceding items, wherein the thickness of the water-soluble polymer film is between 100 nm and 100 μm.
21. The method according to any one of the preceding items, wherein the step of delaminating comprises or consists of mechanically separating the water-soluble transfer stack and the two-dimensional layer from the growth substrate.
22. The method according to any one of the preceding items, wherein for each time the steps i.-iv. are repeated, a further two-dimensional layer is added to the water-soluble transfer stack.
23. The method according to any one of the preceding items, wherein at least a part of the method is repeated by applying the delaminated film to a further two-dimensional material layer, such as an exposed two-dimensional material layer of the further growth stack.
24. The method according to any one of the preceding items, wherein the method is carried out in a roll-to-roll process.
25. A water-soluble transfer stack comprising multilayer two-dimensional material manufactured according to any one of items 1-24.
26. A method for manufacturing a multilayer two-dimensional material on a target substrate, the method comprising:
   a) Obtaining a water-soluble transfer stack comprising multilayer two-dimensional material, comprising:
      i. Providing a growth stack comprising a growth substrate and a two-dimensional material layer;
      ii. Applying an intercalating solution, to the growth stack;
      iii. Applying a transfer layer comprising a water-soluble polymer film, to the growth stack;
      iv. Delaminating the water-soluble polymer film together with the two-dimensional material layer, thereby obtaining a delaminated film, from the growth substrate; and
      v. Repeating steps i.-iv. a number of times, wherein the delaminated film is used as the transfer layer;
   b) Applying said transfer stack to the target substrate.
27. The method according to item 26, wherein the water-soluble transfer stack has been obtained according to any one of items 1-24.
28. Use of a water-soluble transfer stack comprising multilayer two-dimensional material for manufacturing a multilayer two-dimensional material on a target substrate, the use comprising
   a) Obtaining a water-soluble transfer stack, comprising:
      i. Providing a growth stack comprising a growth substrate and a two-dimensional material layer;
      ii. Applying an intercalating solution, to the growth stack;
      iii. Applying a transfer layer comprising a water-soluble polymer film, to the growth stack;
      iv. Delaminating the water-soluble polymer film together with the two-dimensional material layer, thereby obtaining a delaminated film, from the growth substrate; and
      v. Repeating steps i.-iv. a number of times, wherein the delaminated film is used as the transfer layer;
   b) Applying said water-soluble transfer stack to the target substrate;
   thereby manufacturing the multilayer two-dimensional material on the target substrate
29. The use according to item 28, wherein the water-soluble transfer stack has been obtained according to any one of items 1-24.
30. A multilayer two-dimensional material, comprising multiple layers of a two-dimensional material, wherein the average maximum height of roughness is below 50 nm.
31. The multilayer two-dimensional material according to item 30, wherein the material of the two-dimensional material layer is any, or a mixture, of graphene, hexagonal boron nitride, and/or a transition metal dichalcogenides, such as molybdenum disulfide, hafnium disulfide, tungsten diselenide, or a MXene.
32. The multilayer two-dimensional material according to any one of items 30-31, wherein the surface area of each layer of the multilayer two-dimensional material is at least 1 cm².
33. The multilayer two-dimensional material according to any one of items 30-32, wherein said multilayer two-dimensional material is applied to a target substrate, such as SiO₂.

1. A method of manufacturing a water-soluble transfer stack comprising multiple two-dimensional material layers, the method comprising:
i. Providing a growth stack comprising a growth substrate and a two-dimensional material layer;
ii. Applying an intercalating solution to the growth stack;
iii. Applying a transfer layer comprising a water-soluble polymer film, to the growth stack;
iv. Delaminating the water-soluble polymer film together with the two-dimensional material layer, thereby obtaining a delaminated film from the growth substrate; and
v. Repeating steps i.-iv. a number of times, wherein for each repetition the most recently obtained delaminated film is used as the transfer layer;
thereby manufacturing a water-soluble transfer stack comprising multiple two-dimensional material layers.

2. The method according to claim 1, wherein the two-dimensional material is graphene.

3. The method according to claim 1, wherein the multiple two-dimensional material layers of the transfer stack comprises layers of different materials selected from any of graphene, hexagonal boron nitride, transition metal dichalcogenides, and/or MXenes.

4. The method according to any one of the preceding claims, wherein the surface area of each two-dimensional material of the transfer stack is at least 1 cm².

5. The method according to any one of the preceding claims, wherein the step of providing the growth stack comprises growth of the two-dimensional material layer on the growth substrate, such as by chemical vapor deposition growth, and wherein, upon repeating steps i.-iv., the growth substrate is reused for formation of each further two-dimensional material layer.

6. The method according to any one of the preceding claims, wherein the intercalating solution comprises or consists of any of water, an alcohol solution (EtOH or IPA), and/or a salt solution, such as sodium chloride or potassium chloride.

7. The method according to any one of the preceding claims, wherein the step of applying the intercalating solution is adapted such that the intercalating solution intercalates between the growth substrate and the two-dimensional material layer, such as by oxidizing the growth substrate.

8. The method according to any one of the preceding claims, wherein the intercalating solution is applied to the growth substrate at a temperature of at least 40° C., such as between 40° C. and 80° C.

9. The method according to any one of the preceding claims, wherein the step of applying the transfer layer to the growth stack comprises application of vacuum, such as low or medium vacuum.

10. The method according to any one of the preceding claims, wherein the step of applying the transfer layer to the growth stack comprises application of heat, at a temperature of between 100° C. and 180° C. and a pressure, such as a mechanical laminating pressure of between 2-5 bar.

11. The method according to any one of the preceding claims, wherein the step of applying the transfer layer to the growth stack comprises a post-baking step, performed at least at 80° C., more preferably at least at 100° C., yet more preferably at least at 120° C., most preferably at least at 140° C., such as for at least 30 s.

12. The method according to any one of the preceding claims, wherein the transfer layer is applied to the growth stack by any of a roll laminator, a hot roll laminator, a roll-to-roll press, and/or a hot press.

13. The method according to any one of the preceding claims, wherein the material of the water-soluble polymer film is polyvinyl alcohol.

14. The method according to any one of the preceding claims, wherein the thickness of the water-soluble polymer film is between 100 nm and 100 μm.

15. The method according to any one of the preceding claims, wherein for each time the steps i.-iv. are repeated, a further two-dimensional layer is added to the water-soluble transfer stack.

16. The method according to any one of the preceding claims, wherein the step of delaminating comprises or consists of mechanically separating the water-soluble transfer stack and the two-dimensional layer from the growth substrate.

17. The method according to any one of the preceding claims, wherein for each time the steps i.-iv. is repeated, a further two-dimensional layer is added to the water-soluble transfer stack.

18. The method according to any one of the preceding claims, wherein at least a part of the method is repeated by applying the delaminated film to a further two-dimensional material layer, such as an exposed two-dimensional material layer of the further growth stack.

19. The method according to any one of the preceding claims, wherein the method is carried out in a roll-to-roll process.

20. A water-soluble transfer stack comprising multiple two-dimensional material layers manufactured according to the method of any one of claims 1-19.

21. A method for manufacturing multiple two-dimensional material layers on a target substrate, the method comprising:
a) Obtaining a water-soluble transfer stack comprising multilayer two-dimensional material, comprising:
i. Providing a growth stack comprising a growth substrate and a two-dimensional material layer;
ii. Applying an intercalating solution to the growth stack;
iii. Applying a transfer layer comprising a water-soluble polymer film, to the growth stack;
iv. Delaminating the water-soluble polymer film together with the two-dimensional material layer, thereby obtaining a delaminated film, from the growth substrate; and
v. Repeating steps i.-iv. a number of times, wherein for each repetition the most recently obtained delaminated film is used as the transfer layer;
b) Applying said transfer stack to the target substrate.

22. The method according to claim 21, wherein the water-soluble transfer stack is obtained by the method according to any one of claims 1-19.

23. A multilayer two-dimensional material, comprising multiple layers of a two-dimensional material, wherein the average maximum height of roughness is below 50 nm.

24. The multilayer two-dimensional material according to claim 23, wherein the material of the two-dimensional material layer is graphene.

25. The multilayer two-dimensional material according to any one of claims 23-24, wherein the surface area of each layer of the multilayer two-dimensional material is at least 1 cm².
